(19) United States
(12) Patent Application Publication
(10) Pub. No.: US 2004/0231596 A1
(43) Pub. Date: Nov. 25, 2004

(54) Electric arc spray method and apparatus with combustible gas deflection of spray stream

(76) Inventor: Louis C. George, Grand Rapids, MI (US)

Correspondence Address: PRICE HENEVELD COOPER DEWITT & LITTON, LLP, 695 KENMOOR, S.E., P O BOX 2567, GRAND RAPIDS, MI, 49501, US

(21) Appl. No.: 10/440,985

(22) Filed: May 19, 2003

(51) Int. Cl. C23C 16/00

(52) U.S. Cl. 118/722

(57) ABSTRACT

An apparatus for spraying molten metal to form a metallic coating includes an electric arc sprayer having electrically energized consumable metallic wire electrodes that converge to form an electric arc. A stream of non-combustible gas drives the molten metal to form a molten metal particle stream in an initial first direction. A stream of combustible gas is supplied in a transverse direction to deflect the stream of molten metal particles for coating a surface. The combustible gas is preferably mixed with another gas that supplies oxygen to ensure complete combustion.

### BACKGROUND OF THE INVENTION

Various types of devices have been developed for spraying molten metal to metal coat parts. Known wire arc thermal spray devices include a pair of wires that are electrically energized and fed together at a spray head to form an electrical arc that melts the wires, and a stream of compressed air or inert gas is directed at the arc to form a stream of molten metal that can be directed towards the part to be coated.

However, difficulty has been encountered when attempting to coat the inside surfaces such as the cylinder wall of an internal combustion engine. In general, the limited space available within the cylinder or other internal space restricts access of the spray head, making it difficult to achieve a proper surface coating. Various arrangements have been developed in an attempt to provide for coating the interior of such parts. For example, Dunkerley et al. U.S. Pat. No. 5,908,670 discloses an apparatus including two consumable metallic wire electrodes with an atomizing gas supply that produces a molten particle stream. A deflecting gas valve assembly is rotatable relative to the two wires, and deflects the molten particle stream.

Marantz et al. U.S. Pat. No. 5,468,295 discloses a thermal spray coating apparatus having a nozzle with a plurality of ports facing radially inwards toward a coating material particle stream such as an atomized molten metal stream of a two-wire arc thermal spray apparatus. The ports sequentially receive a deflecting gas flow, such that the direction moves circumferentially about the axis of the particle stream.

However, the deflecting gas utilized in existing thermal spray devices cools or quenches the molten particle stream, such that the metal coating produced may not have sufficient bond strength and/or density.

### SUMMARY OF THE INVENTION

One aspect of the present invention is a rotary spray apparatus for spraying molten metal to form a metallic coating. The rotary spray apparatus includes an electric arc sprayer including at least two electrically energized consumable metallic wire electrodes that converge to create an electric arc. A stream of compressed atomizing gas passes through the arc zone formed by the electric arc, and drives a molten metal particle stream in a first direction. A source of combustible gas rotates relative to the at least two wires and deflects the molten metal particle stream in a second direction transverse to the initial first direction towards a surface to be coated, and the combustible gas heats the molten metal particle stream.

Another aspect of the present invention is a method of spraying a metallic coating on an internal surface of a part. The method includes feeding at least two wires in convergence towards one another. The wires are electrically energized to form an arc zone, and a stream of atomizing gas is directed at the arc zone to generate a molten metal particle stream traveling a first direction. The molten metal particle stream is deflected by directing a rotating stream of combustible gas at the molten metal particle stream in a second direction that is transverse to the first direction to direct the molten metal particle stream onto an internal surface to be coated.

Another aspect of the present invention is a spray apparatus for spraying molten metal to form a metallic coating. The spray apparatus includes an electric arc sprayer having at least two electrically energized consumable metallic wire electrodes converging to create an electric arc. The wire electrodes melt to form an arc zone, and a stream of compressed atomizing gas passes through the arc zone and drives a molten metal particle stream in a first direction. The spray apparatus further includes at least one nozzle configured to direct a stream of combustible gas into the molten metal particle stream in a second direction that is transverse to the first direction to deflect the molten metal particle stream onto a surface to be coated.

These and other features, advantages, and objects of the present invention will be further understood and appreciated by those skilled in the art by reference to the following specification, claims, and appended drawings.

### BRIEF DESCRIPTION OF THE DRAWINGS

FIG. 1 is a fragmentary, partially schematic perspective view of a spray apparatus according to the present invention;

FIG. 2 is a schematic view of the metal spray apparatus of FIG. 1;

FIG. 3 is a cross-sectional view of the head of the spray apparatus of FIGS. 1 and 2;

FIG. 4 is a fragmentary view of the nozzle of the spray head of FIG. 3 taken along the line IV-IV; FIG. 3; and

FIG. 5 is a partially schematic fragmentary view of the spray apparatus of the present invention in use.

### DETAILED DESCRIPTION OF PREFERRED EMBODIMENT

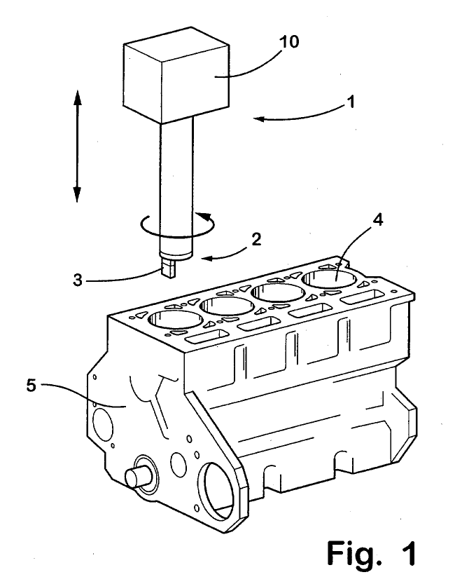

For purposes of description herein, the terms “upper,” “lower, ”“right,” “left,” “rear,” “front,” “vertical,” “horizontal,” and derivatives thereof shall relate to the invention as oriented in FIG. 1. However, it is to be understood that the invention may assume various alternative orientations and step sequences, except where expressly specified to the contrary. It is also to be understood that the specific devices and processes illustrated in the attached drawings and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise.

With reference to FIG. 1, the spray apparatus 1 of the present invention includes a spray head 2 including a rotating nozzle 3 that can be utilized to spray molten metal onto an interior surface such as the inside wall 4 of an engine block 5 of an internal combustion engine.

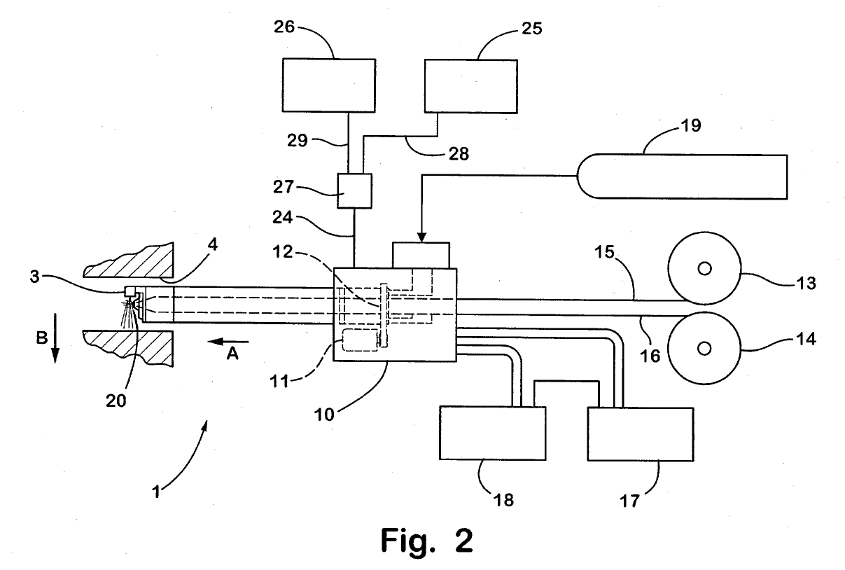

With further reference to FIG. 2, the spray apparatus 1 includes a primary section 10 including an electric motor 11 that rotates the nozzle 3 via a belt 12 or the like. Spools 13 and 14 supply metal wires 15 and 16 to the spray head 2, and a power supply 17 electrifies the wires 15 and 16 to produce an electric arc in a known manner. A controller 18 may be utilized to control the spray apparatus 1. A supply of compressed gas 19, such as air, is supplied to propel a stream of molten metal 20 in a first direction indicated by the arrow “A”. A supply of combustible gas 25 feeds gas such as propane through a line 28 to a mixer 27 where the combustible gas is mixed with air or other oxidizing gas from oxidizing gas source 26 that is supplied through a line 29. In a preferred embodiment, the combustible gas supply 25 utilizes propane. However, other gases such as natural gas, acetylene, hydrogen or the like may also be utilized depending upon the requirements of a particular application. The oxidizing gas supply 26 preferably provides a supply of air or oxygen. The combustible gas supply 25, oxidizing gas supply 26, and mixer 27, and associated regulators, valves, and other such components are commercially available, and therefore will not be described in detail.

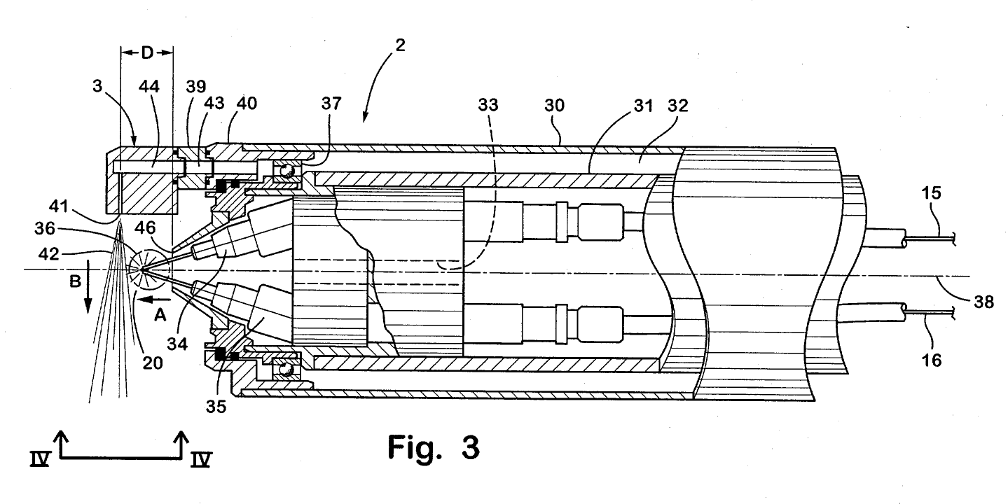

With further reference to FIG. 3, the spray head 2 includes an outer tube 30, and an inner member 31 that form an annular passageway 32 through which the mixture of combustible and oxidizing gas supplied from line 24 (FIG. 2) is supplied. The compressed, non-combustible gas utilized to propel the stream of molten metal 20 in a first direction A is supplied through a port 33. Wire guide assemblies 34 and 35 direct the consumable wires 15 and 16 into the arc zone 36 in a known manner. The wires 15 and 16 are electrically energized, such that a short occurs between the two wires, thereby melting the wires. The compressed gas supplied through port 33 propels the molten metal particles in a stream 20 in an initial first direction A. The outer tube 30 is rotatably supported on ball bearings 37, and rotates about the inner member 31 and the wire guides 34 and 35. The nozzle 3 is secured to the outer tube 30, such that it rotates about the axis 38 of the spray head 2. Nozzle 3 includes one or more orifices 41 that produce a stream 42 of the combustible gas air mixture in a transverse direction indicated by the arrow “B”. A spacer 39 may be utilized to mount the nozzle 3 to the end member 40 of the spray head 2. The spacer 39 can have different thicknesses, such that distance “D” between the orifice 41 and the end 46 of the spray head can be adjusted. The position of the orifice 41 can therefore also be varied relative to the arc zone 36. This permits the stream of combustible gas and air 42 to be positioned at a desired location downstream of the arc zone 36, as required for a particular application. In general, the orifice 41 can be positioned further downstream than in prior non-combustible gas units because the combustible gas heats the stream of molten metal 20 as it is deflected, such that excessive cooling does not occur. A spacer 39 includes an internal passageway 43 that provides flow of the combustible gas and air or oxygen mixture from the passageway 32 through the passageway 43 and 44, and out through the orifice 41. The spacer 39 may include threads or the like (not shown) to provide for attachment to the end member 40 and nozzle 3. Alternately, the overall length of the nozzle 3 may be varied to adjust the position of the orifice 41.

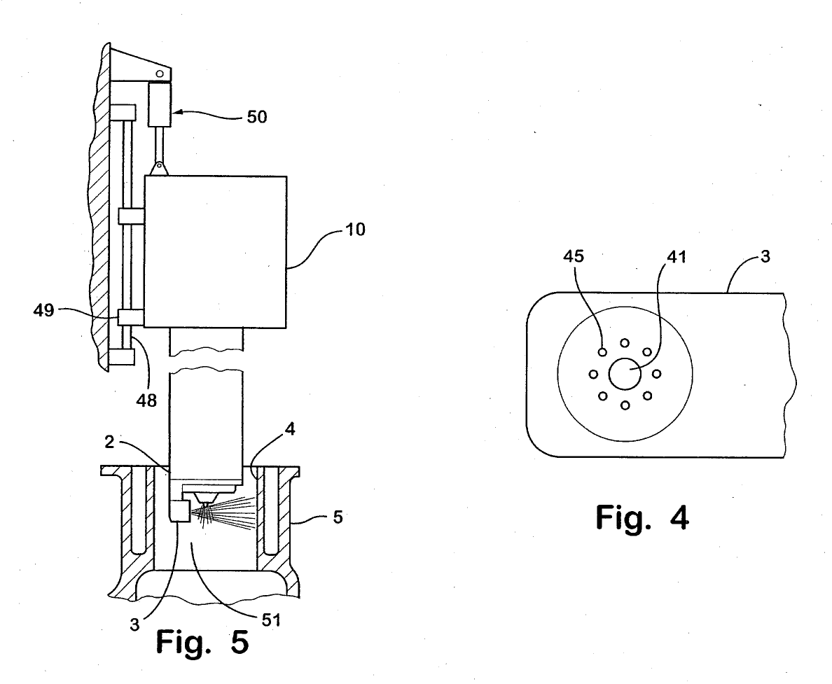

With further reference to FIG. 4, in a preferred embodiment the nozzle 3 includes an enlarged center orifice 41 and a plurality of smaller orifices 45 positioned about the center orifice 41. In use, the mixture of combustible gas and air exits through the orifices 41 and 45, and the smaller orifices 45 “shield” the combustible gas exiting from orifice 41 and prevent or reduce oxidization of the molten metal.

As illustrated in FIG. 5, the spray apparatus may be movably mounted utilizing using linear guides such as guide bars 48 and pillow blocks 49 or the like, and an actuator such as a pneumatic cylinder 50 may be utilized to vertically shift the spray apparatus into and out of the internal cavity 51 of an engine block 5 or the like. Other mechanisms such as robotic devices providing for linear travel may also be utilized. In use, the spray head 2 is shifted vertically while the nozzle 3 is rotated to completely coat the internal sidewall 4 of the engine block 5 with the molten metal.

The wires 15 and 16 may be made of a wide variety of metals or alloys depending upon the requirements of a particular application. The combustible gas is preferably mixed with air or other oxidizing gas to provide for full combustion. However, the combustible gas may also be supplied by itself, without mixing with an oxidizing gas. The flow rates, pressures and the like are adjusted as required for a given application. Similarly, the rotation rate of nozzle 3 and linear travel velocity are also adjusted as required.

In the foregoing description, it will be readily appreciated by those skilled in the art that modifications may be made to the invention without departing from the concepts disclosed herein. Such modifications are to be considered as included in the following claims, unless these claims by their language expressly state otherwise.

The invention claimed is:

1. A rotary spray apparatus for spraying molten metal to form a metallic coating, comprising:
an electric arc sprayer comprising at least two electrically energized consumable metallic wire electrodes converging to create an electric arc, said wire electrodes melting to form an arc zone;
a stream of compressed atomizing gas passing through said arc zone and driving a molten metal particle stream in an initial first direction; and
a source of deflecting combustible gas rotating relative to said at least two wires and deflecting said molten metal particle stream in a second direction transverse to said initial first direction towards a surface to be coated, and heating said molten metal particle stream.

2. The rotary spray apparatus of claim 1, wherein:
said source of deflecting combustible gas comprises a rotatable nozzle.

3. The rotary spray apparatus of claim 2, wherein:
said second direction is substantially orthogonal to said first direction.

4. The rotary spray apparatus of claim 2, wherein:
said deflecting combustible gas is supplied in a substantially steady flow.

5. The rotary spray apparatus of claim 1, wherein:
said combustible gas comprises propane gas.

6. The rotary spray apparatus of claim 1, wherein:
said wire electrodes are made of a metallic material.

7. A method of spraying a metallic coating on an internal surface of a part, comprising:
feeding at least two wires in convergence towards one another;
electrically energizing said at least two wires to form an arc zone;
directing a stream of atomizing gas at said arc zone to generate a molten metal particle stream traveling in a first direction; and
deflecting said molten metal particle stream by directing a rotating stream of combustible gas at said molten metal particle stream in a second direction that is transverse to said first direction to direct said molten metal particle stream onto an internal surface to be coated.

8. The method of claim 7, wherein:
an oxidizing gas is mixed with said combustible gas.

9. The method of claim 8, wherein:
said oxidizing gas comprises air.

10. The method of claim 7, wherein:
said stream of combustible gas is directed at said stream of molten metal downstream of said arc zone.

11. The method of claim 10, wherein:
said second direction is orthogonal to said first direction.

12. The method of claim 7, wherein:
said combustible gas comprises propane.

13. A spray apparatus for spraying molten metal to form a metallic coating, comprising:
an electric arc sprayer comprising at least two electrically energized consumable metallic wire electrodes converging to create an electric arc, said wire electrodes melting to form an arc zone;
a stream of compressed atomizing gas passing through said arc zone and driving a molten metal particle stream in an initial first direction; and
at least one nozzle configured to direct a stream of combustible gas into said molten metal particle stream in a second direction transverse to said first direction to deflect said molten metal particle stream onto a surface to be coated.

14. The rotary spray apparatus of claim 13, wherein:
said second direction is substantially orthogonal to said first direction.

15. The rotary spray apparatus of claim 14, wherein:
said deflecting combustible gas is supplied in a substantially steady flow.

16. The rotary spray apparatus of claim 13, wherein:
said sprayer defines an axis extending in said first direction;
the position of said nozzle is adjustable, such that said nozzle can be shifted along said axis to selectively position said stream of combustible gas at a selected position downstream of said arc zone.

17. The rotary spray apparatus of claim 16, wherein:
said spray apparatus includes a head assembly including wire guides to direct said wire electrodes to said arc zone, said nozzle extending from an end of said head; and including:
at least one spacer between said nozzle and said head providing adjustment of the position of said nozzle relative to said head.

18. The rotary spray apparatus of claim 13, including:
a source of combustible gas supplying said nozzle with said combustible gas;
a source of oxidizing gas coupled to said source of combustible gas and mixing therewith, such that a mixture of said combustible gas and said oxidizing gas is supplied to said nozzle.

19. The rotary spray apparatus of claim 18, wherein:
said nozzle rotates about said arc zone to coat interior surfaces of parts.
